(19) United States
(12) Patent Application Publication
(10) Pub. No.: US 2011/0073860 A1
(43) Pub. Date: Mar. 31, 2011

(54) SEMICONDUCTOR DEVICE AND DISPLAY DEVICE

(75) Inventors: Michihiro Kanno, Kanagawa (JP); Takahiro Kawamura, Kanagawa (JP)

(73) Assignee: SONY CORPORATION, Tokyo (JP)

(21) Appl. No.: 12/886,983

(22) Filed: Sep. 21, 2010

(30) Foreign Application Priority Data
Sep. 30, 2009 (JP) 2009-227013

(51) Int. Cl. H01L 29/786; H01L 21/336

(52) U.S. Cl. 257/57; 438/151; 257/66; 257/E29.289; 257/E29.292; 257/E21.412

(57) ABSTRACT

A thin film transistor comprising an insulating film, a gate electrode embedded in a superficial portion of the insulating film, a gate insulating film on the gate electrode and the insulating film, a semiconductor film on the gate insulating film, a channel protection film on a portion of the semiconductor film with end surfaces which have a forward tapered slope, a first electrode on the semiconductor film which mounts onto one tapered side of the channel protection film, and a second electrode on the semiconductor film which mounts onto the other tapered side of the channel protection film, where an edge of the gate electrode closest to the first electrode is offset towards the second electrode from the point where the first electrode abuts the semiconductor film.

### CROSS-REFERENCE TO RELATED APPLICATIONS

The present application claims priority to Japanese Priority Patent Application JP 2009-227013 filed in the Japan Patent Office on Sep. 30, 2009, the entire contents of which is hereby incorporated by reference.

### BACKGROUND OF THE INVENTION

The present invention relates to a semiconductor device including a thin-film transistor that has a gate electrode, which controls formation of a channel, and two source/drain electrodes formed on a semiconductor thin film layered on a substrate in an insulated state. In addition, the present invention relates to a display device in which the thin-film transistor is adopted as an element of a pixel circuit.

### BACKGROUND OF INVENTION

When a thin-film transistor is adopted as one element of a pixel circuit included in a display device, if a current flowing between a source and a drain with a gate inactivated is large, a flickering point or a glowing point appears in a display image and is detected as an abnormality in a pixel property. Therefore, the thin-film transistor is requested to have an off-state current thereof suppressed. In order to raise a luminance, it is important to lower an on-state resistance so as to ensure a necessary on-state current. Therefore, the ratio of the on-state current of the thin-film transistor to the off-state current thereof (on-off ratio) is requested to be raised. In addition, the thin-film transistor is requested to exhibit high responsiveness to control of a current, that is, to exhibit an excellent frequency characteristic.

Aside from the element of the pixel circuit included in the display device, circuit elements are generally demanded to meet the foregoing requests according to the characteristics of a circuit in which the circuit elements are employed.

A so-called planar thin-film transistor (TFT) structure having a channel formation region defined in a semiconductor film and having two source-drain regions defined on the sides of the channel formation region is known. See, for example, Japanese patent applications JP-A-2002-313808 and JP-A-2006-313776.

In Japanese patent application JP-A-2002-313808, for a planar thin-film transistor, a gate-overlapped lightly-doped drain (LDD) structure is proposed as a method for suppressing an off-state current without decreasing an on-state current. In this case, a gate electrode has a two-layer structure overlapping an LDD region. The LDD region containing an impurity at a low concentration is formed in a self-aligned manner in the course of formation of the two-layer gate. Since the LDD region is formed in the self-aligned manner, a misalignment of the LDD region with a source/drain region can be ignored. A variance in a property occurring during fabrication can be suppressed.

In the above structure, since the gate electrode of the second layer overlaps the LDD region, when the thin-film transistor is turned on, the conductivity of the LDD region improves and an on-state resistance decreases. The structure is called a gate-overlapped lightly-doped drain (GO LDD) structure.

When the second gate electrode of the upper layer that overlaps the LDD region is made of a conducting material that offers a higher resistance than the first gate electrode of the lower layer opposed to the channel formation region does, a parasitic capacitance is decreased.

According to Japanese patent application JP-A-2006-313776, an insulating film disposed above an LDD region is made thick in order to relax an electric field induced by a gate voltage. In addition, the concentration of an impurity in a drain region is devised to exhibit a gradient.

In addition, a so-called staggered TFT structure is known, See, for example, Japanese patent applications JP-A-2008-258345 and JP-A-5-275698.

This type of TFT is structured to have a source/drain impurity region formed in a layer (thin film) different from a layer of a semiconductor thin film in which a channel is formed. The structure falls into a bottom gate staggered type (inverted staggered type) in which a gate electrode is disposed in a layer below the semiconductor thin film, and a top gate staggered type (staggered type) in which the gate electrode is disposed in an upper layer.

According to Japanese patent application JP-A-2008-258345, in the bottom gate or top gate staggered structure, the concentration of an impurity in an impurity layer in a source/drain region is made lower toward the channel in order to decrease an off-state current.

In Japanese patent application JP-A-5-275698, a layout shape in which an end surface that is seen through planar view to have irregularities is formed on a gate electrode, and a source electrode and a drain electrode partly and discretely overlap the irregular end surface is proposed for the purpose of decreasing both an off-state current and a parasitic capacitance.

As described in Japanese patent application JP-A-2002-313808, a structure for decreasing a leakage current using an LDD region can decrease the leakage current due to relaxation of an electric field induced on an edge of the LDD region. However, in this structure, since a series resistance caused by a current path is increased by a series resistor realized with the LDD region formed uniformly in the current path. This brings about a loss in an on-state current.

When the concentration of an impurity in the LDD region is raised (a resistance is lowered) in order to preserve an on-state current, a carrier generation rate rises in a region of high electric-field intensities on an edge of a drain abutting on a channel, and an off-state current increases.

According to the solution that employs the LDD region, a decrease in an off-state current is traded off with preservation of an on-state current.

Each of Japanese patent applications JP-A-2006-313776 and JP-A-2008-258345 has the demerit that the structure of an insulating film is complex or that a gradient in an impurity concentration varies. Therefore, an effect of a decrease in an off-state current is not exerted satisfactorily.

A decrease in a parasitic capacitance is significant. According to all of Japanese patent applications JP-A-2002-313808, JP-A-2006-313776 and JP-A-2008-258345, a gate electrode overlaps a drain region or a source region. If the area of the overlap is wide, the parasitic capacitance increases to hinder a high-speed operation.

According to Japanese patent application JP-A-5-275698, the trade-off between a decrease in a parasitic capacitance and a decrease in a leakage current is loosened. More particularly, according to the patent document 4, a layout in which a convex part of a gate electrode discretely overlaps the edge of a drain electrode on which the drain electrode abuts on a semiconductor thin film is adopted for the bottom gate staggered structure.

However, the structure has a drawback that since a channel region to be dominated by an electric field induced in a gate electrode is halved in the direction of the width of the gate (a direction orthogonal to the direction of a channel current), a current driving ability becomes insufficient to fail in feeding a large amount of current identical to that to be fed when an on-state resistance is large. Namely, the structure is infeasible because although the trade-off between the parasitic capacitance and leakage current is somewhat loosened, a nominal on-state resistance increases.

As mentioned above, the technologies described in the patent documents 1 to 4 have failed to resolve or loosen the trade-off between a parasitic capacitance and a leakage current without the sacrifice of an on-state resistance. Therefore, when any of the existent thin-film transistors is adopted as an element of a pixel circuit included in a display device, an image is not displayed at a high speed with a glowing point or a flickering point prevented.

Thus, there is a need for a semiconductor device that includes a thin-film transistor allowing the trade-off between a parasitic capacitance and a leakage current to be resolved or loosened without the sacrifice of an on-state resistance. Further, there is a need for a display device having such a thin-film transistor adopted as an element of a pixel circuit.

### SUMMARY OF THE INVENTION

One embodiment consistent with the present invention includes a thin film transistor comprising an insulating film, a gate electrode embedded in a superficial portion of the insulating film, a gate insulating film on the gate electrode and the insulating film, a semiconductor film on the gate insulating film, a channel protection film on a portion of the semiconductor film with end surfaces which have a forward tapered slope, a first electrode on the semiconductor film which mounts onto one tapered side of the channel protection film, and a second electrode on the semiconductor film which mounts onto the other tapered side of the channel protection film where an edge of the gate electrode closest to the first electrode is offset towards the second electrode from the point where the first electrode abuts the semiconductor film.

In another embodiment consistent with the present invention, an edge of the gate electrode closest to the second electrode is offset towards the first electrode from the point where the second electrode abuts the semiconductor film.

In another embodiment consistent with the present invention, the lower portions of the channel protection layer which abut the second electrode creates a drain edge, and the lower portions of the channel protection layer which abut the first electrode creates a source edge

In another embodiment consistent with the present invention, the gate insulating film is a single layer film.

In another embodiment consistent with the present invention, the semiconductor film is made of a microcrystalline silicon;

In another embodiment consistent with the present invention, the main wiring film is made of a low resistance wiring material.

In another embodiment consistent with the present invention, the lower electrode is made of titanium.

In another embodiment consistent with the present invention, the center of the gate electrode is offset from the center of the channel protection film.

In another embodiment consistent with the present invention, the surface of the gate electrode is flush with the surface of the insulating film.

Another embodiment consistent with the present invention recites a method of manufacturing a thin film transistor comprising the steps of forming an insulating film, forming a gate electrode embedded in a superficial portion of the insulating film, forming a gate insulating film over the gate electrode and the insulating film, forming a semiconductor film on the gate insulating film, forming a channel protection film on the semiconductor film with end surfaces which have a forward tapered slope, forming a first electrode on one tapered side of the channel protection film, and forming a second electrode on one tapered side of the channel protection film where an edge of the gate electrode closest to the first electrode is offset towards the second electrode from the point where the first electrode abuts the semiconductor film.

In another embodiment consistent with the present invention, an edge of the gate electrode closest to the second electrode is offset towards the first electrode from the point where the second electrode abuts the semiconductor film.

In another embodiment consistent with the present invention, the first electrode includes an upper electrode film above a main wiring film which is above a lower electrode film which is above a semiconductor film.

In another embodiment consistent with the present invention, the lower portions of the channel protection layer which abuts the second electrode serves as a drain edge, and the lower portions of the channel protection layer which abuts the first electrode serves as a source edge

In another embodiment consistent with the present invention, the gate insulating film is a single layer film.

In another embodiment consistent with the present invention, the semiconductor film is made of a microcrystalline silicon.

In another embodiment consistent with the present invention, the main wiring film is made of a low resistance wiring material.

In another embodiment consistent with the present invention, the lower electrode is made of titanium.

In another embodiment consistent with the present invention, the center of the gate electrode is offset from the center of the channel protection film.

In another embodiment consistent with the present invention, the surface of the gate electrode is flush with the surface of the insulating film. Other systems, methods, features, and advantages of the present invention will be or will become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE DRAWINGS

FIG. 1 is a plan view of a major portion of a TFT in accordance with a first embodiment;

FIG. 2 is a diagram showing the sectional structure of the major portion along an A-A cutting-plane line shown in FIG. 1;

FIGS. 3A to 3E are sectional views showing the process of fabricating the TFT structure in accordance with the first embodiment;

FIG. 4 is a plan view of a major portion of a TFT in accordance with a second embodiment;

FIG. 5 is a diagram showing the sectional structure of the major portion along a B-B cutting-plane line shown in FIG. 4;

FIG. 6 is a plan view of a major portion of a TFT in accordance with a third embodiment;

FIG. 7 is a diagram showing the sectional structure of the major portion along a C-C cutting-plane line shown in FIG. 6;

FIGS. 8A and 8B are a plan view schematically showing a TFT in accordance with a fourth embodiment, and a diagram schematically showing a construction in a vertical direction;

FIGS. 9A to 9C are plan views schematically showing TFTs in accordance with fifth and sixth embodiments respectively, and a diagram schematically showing a construction in a vertical direction;

FIGS. 10A to 10E are sectional views showing the process of fabricating the TFTs in accordance with the fifth and sixth embodiments;

FIGS. 11A to 11C are plan views schematically showing TFTs in accordance with seventh and eight embodiments, and a diagram schematically showing a construction in a vertical direction;

FIGS. 12A to 12C are plan views schematically showing TFTs in accordance with ninth and tenth embodiments, and a diagram schematically showing a construction in a vertical direction;

FIGS. 13A to 13C are plan views schematically showing TFTs in accordance with eleventh and twelfth embodiments, and a diagram schematically showing a construction in a vertical direction;

FIGS. 14A to 14E are plan views schematically showing TFTs in accordance with thirteenth to sixteenth embodiments, and a diagram schematically showing a construction in a vertical direction;

FIGS. 15A and 15B are a plan view of a TFT in accordance with a comparative example, and a three-dimensional graph indicating the results of simulation performed to create an electric-field distribution;

FIG. 16 is a graph indicating a leakage property of the TFT in accordance with the comparative example;

FIG. 17 is a block diagram of an organic electroluminescent (EL) display in accordance with seventeenth embodiment; and

FIG. 18 is a circuit diagram of a pixel circuit included in the organic EL display shown in FIG. 17.

### DESCRIPTION OF THE PRESENTLY PREFERRED EMBODIMENTS

While various embodiments of the present invention have been described, it will be apparent to those of skill in the art that many more embodiments and implementations are possible that are within the scope of this invention. Accordingly, the present invention is not to be restricted except in light of the attached claims and their equivalents

According to the foregoing construction, when at least one of the two source/drain electrodes functions as a drain electrode, a current is concentrated on the contour portion of the region in which the electrode serving as the drain abuts on the semiconductor film. At this time, a current flows from the region of the electrode, which is close to the contour portion, to the channel formation region by way of the contour portion in which a resistance caused by the current path is minimized. A current flowing from the other part of the electrode is concentrated on the edges of the contour portion, that is, two edge points. Even when the length of the contour portion is squared with the width of the source/drain electrode serving as the drain (normally, the length in the direction of the width of a channel, or a channel width direction), since a stress is concentrated on the edges of the electrode, the current is likely to be concentrated on the edges. In any case, a current is likely to be concentrated on the two edge points other than the other points on the contour portion.

The above phenomenon takes place not only when the thin-film transistor is turned on but also when the thin-film transistor is turned off. Namely, assuming that an n-channel transistor is taken for instance, when the transistor is turned off, the source and drain thereof are biased, and the gate thereof is biased to 0 V or a negative voltage that is lower than a voltage level to which the gate is set when the transistor is turned on. At this time, a current is about to flow due to the bias applied to the source and drain. However, since a channel is forcibly disconnected by the bias applied to the gate, the current is blocked. However, an off-state current flows through a leakage path such as a path running through the drain and the deep part of a substrate. In this case, the off-state current is concentrated on the edges of the contour portion of the source/drain electrode serving as the drain (two edge points). The wider the area of the electrode is, the more intense the concentration of the current on the contour portion is. Even when the two edge points are the edges of an electrode layer, the concentration is intensified.

The embodiment of the present invention adopts a layout pattern in which the two edge points are located outside the gate electrode, or more preferably, separated from the gate electrode by a certain distance or longer.

As far as the n-channel transistor is concerned, when electrons out of carriers generated in a region of high electric-field intensities in a channel near an edge of a drain due to ion impacts flow into the drain electrode, and holes flow through a path in the deep part of a substrate, an off-state current is generally produced. This phenomenon is markedly manifested in an operating domain within which a voltage between a gate and a drain gets higher with the gate negatively biased and the drain positively highly biased.

A leakage current has a component dependent on the width of a channel in a transistor and a component independent thereof. The component independent of the channel width is a leakage component derived from an edge on which a semiconductor film that determines the channel width and a drain electrode abut on each other. For the foregoing reasons, the component independent of the channel width is dominated by a current that flows along a path running through two edge points. In the embodiment of the present invention, the gate electrode is separated from the two edge points. At this time, once a place where carriers are derived from impact ionization is a bit separated from an edge of an electrode on which a leak current is likely to be concentrated, an off-state current is drastically decreased.

A thin-film transistor (TFT) in accordance with an embodiment of the present invention has a gate electrode, a semiconductor thin film in which a channel is formed, a gate insulating film, and two source/drain electrodes layered within a laminated structure that is layered on a substrate having at least an insulating surface.

For a thin-film transistor for which a polycrystalline silicon is adopted as a semiconductor film material, since relatively high-temperature thermal processing can be employed, ion implantation and impurity activation are performed at fabrication steps. Therefore, a so-called planar TFT structure having a channel formation region and two source/drain regions formed in a semiconductor film is preferably adopted. The two source/drain regions are formed as subregions in the semiconductor film that has a reverse-conducting impurity introduced at a relatively high concentration into a position at which the source/drain regions are seen through planar view to sandwich a channel region.

The planar TFT structure falls into a top gate type and a bottom gate type according to whether a gate electrode is disposed on the top side of a semiconductor thin film (opposite to a substrate) or on the bottom side thereof (the substrate). The type in which the present invention can be implemented is the bottom gate planar type in consideration of the fact that a polycrystalline silicon is adopted as the semiconductor film material. Nevertheless, the application of the present invention to the top gate planar type is not discarded.

When a non-crystalline silicon or a microcrystalline silicon is adopted, since a semiconductor film has to be formed at a low temperature, a so-called staggered type in which a channel formation region and a source/drain region are formed in different semiconductor films is preferably adopted. The TFT structure having a gate electrode formed on the bottom side of a source/drain region is called a bottom gate staggered type, while the TFT structure having the gate electrode formed on the top side of the source/drain region is called a top gate staggered type. The bottom gate staggered type may be referred to as an inverted staggered type.

In one embodiment consistent with the present invention, a region in which at least one of two source/drain electrodes abuts on a semiconductor film in which a channel is formed is taken into account. The region may be a planar region in which the surface of the source/drain electrode abuts on the semiconductor film or may be a lateral region in which the flank of the source/drain electrode abuts on the semiconductor film.

In the region, a portion of the contour of the source/drain electrode is defined, and points at the ends of the contour portion shall be called edge points.

Under the foregoing preconditions, a requirement for application of the present invention is that the two edge points be seen through planar view (that is, in a layout pattern) to lie outside a gate electrode. Exemplary embodiments in which the requirement is met will be described later. Layout patterns (cases) described below are conceivable according to how the gate electrode overlaps the contour portion whose ends are regarded as edge points.

A (first) case where the gate electrode and contour portion do not overlap is also encompassed in the scope of the present invention.

In contrast, the gate electrode overlaps the contour portion of the source/drain electrode between the two edge points at one position on the contour portion. More particularly, this case falls into a second case where the convex part of the gate electrode overlaps a linear contour portion, and a third case where a linear edge of the gate electrode overlaps a convex part of the contour portion. In addition, there is a fourth case where the width of the gate electrode is smaller than the width of the contour portion, and the gate electrode overlaps the contour portion over the entire width thereof.

A way of defining the contour portion varies depending on whether a semiconductor channel protection film that functions as an etching stopper is present. This will be detailed later in relation to embodiments.

The first embodiment relates to a bottom gate staggered TFT and is concerned with the first case where a gate electrode does not overlap a contour portion.

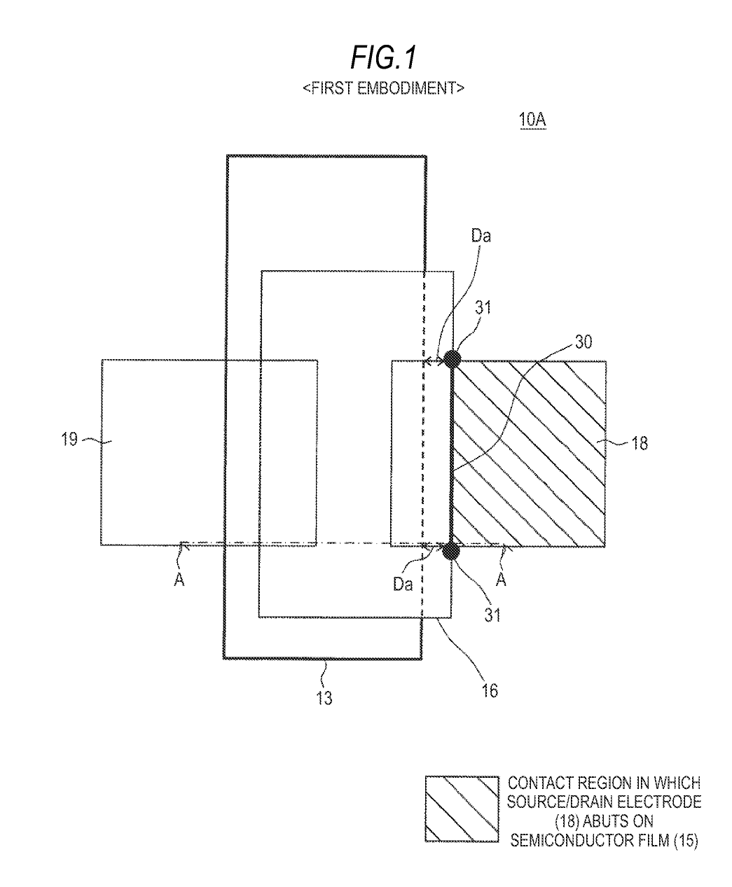

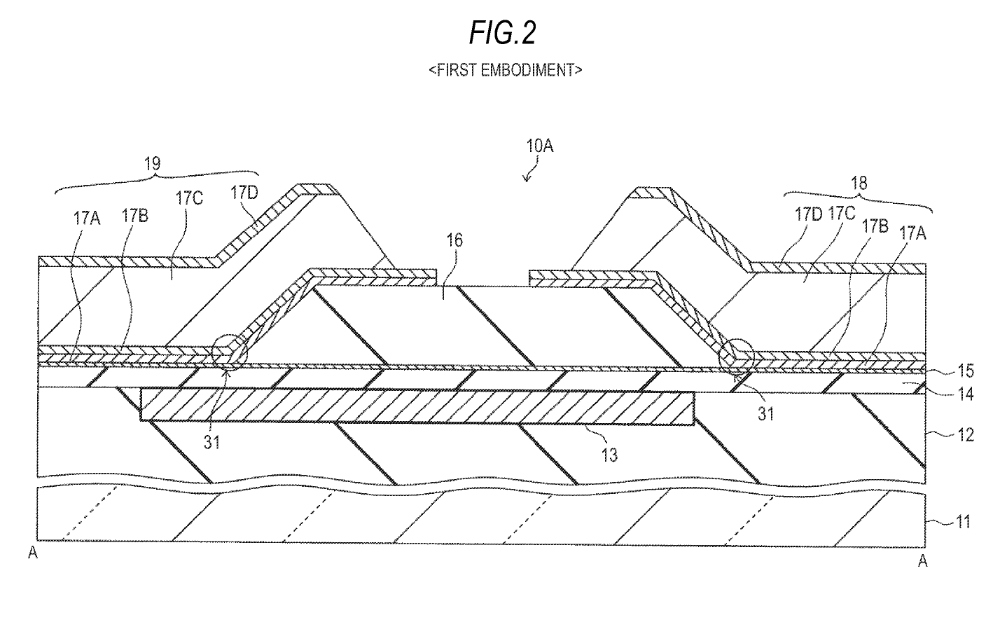

FIG. 1 is a plan view of a TFT, and FIG. 2 is a sectional structural view of the TFT along an A-A cutting-plane line shown in FIG. 1.

In a TFT 10A shown in FIG. 2, a gate electrode 13 including a predetermined gate metal layer (GM) made of, a high-fusing point metal such as, but not limited to, molybdenum (Mo) is formed on a substrate 11 made of glass or the like via a bed layer (a kind of insulating layer). The gate electrode 13 has a thickness of about several tens of nanometers, such as, but not limited to, about 65 nm.

The gate electrode 13 shares an internal wiring with the other elements of, for example, a display pixel circuit. Therefore, the gate electrode 13 is, as shown in FIG. 1, formed like an elongated wiring.

As shown in FIG. 2, the gate electrode 13 is preferably embedded in the superficial part of an insulating surface 12. This is intended to make the insulating layer 12 and gate electrode 13 flush with each other. When the insulating layer 12 and gate electrode 13 are flush with each other, it means that the gate electrode is not uneven with respect to the insulating layer. Therefore, since a film stress is not imposed, concentration of an electric field on an upper semiconductor film or on an electrode contact part can be alleviated. But for such a drawback, the gate electrode 13 may be formed on the surface of the insulating layer 12 at a step of forming and processing a gate electrode film (a molybdenum film).

A gate insulating film 14 is formed to cover the surface of the gate electrode 13 and the surface of the insulating layer 12 surrounding the gate electrode. A semiconductor film 15 made of an amorphous silicon (α-Si) or a microcrystalline silicon (μ-cSi) is formed on the gate insulating film 14.

The gate insulating film 14 may be a single layer of a silicon oxide film or may be a multilayer film. In the case of the multilayer film, the multilayer film preferably includes a lower layer of a silicon nitride (SiN) film and an upper layer of a silicon dioxide (SiO₂) film. The thickness of the silicon nitride film ranges from ten and several nanometers to several tens of nanometers, for example, is 20 nm. The thickness of the silicon dioxide film ranges from one hundred and several tens of nanometers to several hundreds of nanometers, for example, is 290 nm.

The semiconductor film 15 has one pattern isolated for each TFT. In the sectional view of FIG. 2, the semiconductor film 15 is formed across the upper surface of the gate insulating film 14 so as to cover the gate insulating film 14. When the semiconductor film 15 is made of a microcrystalline silicon, the thickness thereof is as small as ten and several nanometers, such as, but not limited to, 15 nm.

A semiconductor channel protection film 16 realized with a relatively thick insulating film having a rectangular pattern shown in FIG. 1 is formed on the semiconductor film 15. The preferable end surface of the semiconductor channel protection film 16 is, as shown in FIG. 2, forward tapered to have a moderate slope. A first source/drain (SD) electrode 18 and a second source/drain (SD) electrode 19 are formed to mount the slope of the semiconductor channel protection film 16 from the left and right sides thereof in the direction of a channel (the direction of the illustrated section) toward the center of the channel.

The first source/drain electrode 18 functions as a drain electrode, and the second source/drain electrode 19 functions as a source electrode. In this case, a so-called drain edge refers to an edge of a contact region, in which the first source/drain electrode 18 abuts on the semiconductor film 15, near the center of the channel. The edge of the contact region is, in the first embodiment, as indicated with a boldfaced solid line in FIG. 1, a line extending in a so-called channel width direction orthogonal to the direction of the channel (a so-called channel length direction). In FIG. 1, the contact region in which the first source/drain electrode 18 abuts on the semiconductor film 15 is shown as a hatched area. The line drawn with the boldfaced solid line refers to a portion of the contour of the region in which the first source/drain electrode 18 abuts on the semiconductor film 15. Hereinafter, the edge of the contact region near the center of the channel shall be called a counter portion 30. The ends of the counter portion 30 shall be called edge points 31.

Even for the second source/drain electrode 19, as shown in FIG. 1, the counter portion 30 and edge points 31 are defined.

Each of the first source/drain electrode 18 and second source/drain electrode 19 is, in the present embodiment, composed of four layers. Specifically, each of the first and second source/drain electrodes 18 and 19 has a source/drain semiconductor film 17A in which a source/drain region is formed, a lower electrode film 17B, a main wiring film 17C, and an upper electrode film 17D layered in that order from the lowest layer.

The source/drain semiconductor film 17A is a semiconductor film having, for example, an n-type impurity applied thereto at a high concentration. In the staggered structure, the semiconductor film in which a source/drain region is formed is formed as a film different from the semiconductor film 15 in which a channel is formed. The thickness of the source/drain semiconductor film 17A is several tens of nanometers, for example, 50 nm.

The thick main wiring film 17C is made of a low-resistance wiring material such as, but not limited to, aluminum. In this case, a thin film made of a high-fusing point metal or the like is coated on the upper and lower sides of the main wiring film 17C in order to prevent reaction to the bed layer or prevent reflection derived from photolithography. The main wiring film 17C is realized with an aluminum film having a thickness that ranges from several hundreds of nanometers to one thousand and one hundred nanometers, for example, 900 nm thick, and the lower electrode film 17B is realized with a titanium film of, for example, about 50 nm thick. The upper electrode film 17D is realized with a molybdenum film of, for example, about 50 nm thick.

The semiconductor channel protection film 16 protects the channel formation region from etching to be performed to process the first and second source/drain electrodes 18 and 19. The first and second source/drain electrodes 18 and 19 are thick enough to ensure the protection, which is helpful in balancing total stresses to be imposed on the first and second source/drain electrodes 18 and 19.

The region in the semiconductor film 15 covered with the semiconductor channel protection film 16 is the channel formation region. The lower edges of the slope of the semiconductor channel protection film 16 serve as a drain edge and a source edge. FIG. 2 shows the section along an A-A cutting-plane line shown in FIG. 1. The edge points 31 are located near the edge of the slope of the semiconductor channel protection film 16.

The present embodiment has a feature that the two edge points 31 is seen through planar view to lie outside the gate electrode 13.

In the present embodiment, an offset gate structure is adopted so that the drain-side edge points 31 (edge points 31 on the right side of FIG. 1 or FIG. 2), on which an electric field is concentrated, can be separated from the gate electrode 13. In other words, the gate electrode 13 is offset so that the center of the gate electrode 13 in the width thereof can be deviated from the center of the channel formation region toward the source electrode.

Preferably, the distance Da (FIG. 1) from each of the edge points 31 to the edge of the gate electrode 13 is equal to or smaller than a predetermined distance D0.

At the edge points 31 which the contours of the semiconductor channel protection film 16 and first source/drain electrode 18 that overlap each other pass, a stress to be imposed on the lower semiconductor film 15 is large. This is a factor of increasing a leakage through the very thin semiconductor film 15. Specifically, for example, assuming that a positive voltage is applied to the first source/drain electrode 18 with the second source/drain electrode 19 set to 0 V, since the resistivity of the first source/drain electrode 18 is low, a current is concentrated on the contour portion 30 shown in FIG. 1 and located closest to the channel formation region. Above all, an electric field is likely to be concentrated on the edge points 31 due to stresses. A large amount of current flows through the edge points 31.

The foregoing phenomenon takes place not only when the TFT is turned on but also when the TFT is turned off. Specifically, assuming that an n-channel type TFT is taken for instance, when the TFT is off, the source and drain (first source/drain electrode 18 and second source/drain electrode 19) thereof are biased, and the gate electrode 13 is biased to 0 V or a negative voltage that is lower than a voltage level to the gate electrode is set when the TFT is on. A current is about to flow due to the bias voltage between the source and drain. However, the channel is forcibly disconnected with the bias voltage across the gate, the current is blocked. Nevertheless, an off-state current flows along a leakage path such as a path running through the drain electrode (first source/drain electrode 18) and the deep part of the substrate. In this case, the off-state current is, like an on-state current, concentrated on the ends of the contour portion 30 (two edge points 31) of the source/drain electrode (first source/drain electrode 18) serving as a drain. When the area of the electrode is wider than that of the contour portion 30, the concentration of the current becomes more intense. Even when the two edge points are points on the edge of an electrode layer (the present embodiment), the concentration is intensified.

The present embodiment adopts the layout pattern in which the two edge points 31 are located outside the gate electrode 13, or more preferably, are separated from the gate electrode by a certain distance D0 or more.

As far as an n-channel TFT is concerned, when electrons among carriers derived from ion impacts occurring in a region of high electric-field intensities in a channel near a drain edge flow into a drain electrode (first source/drain electrode 18), and holes flow along a path in the deep part of a substrate, an off-state current is generated. This phenomenon is markedly manifested in an operating domain within which a voltage between a gate and a drain gets higher with the gate biased negatively and the drain positively highly biased.

Further, a leakage current has a component dependent on the width of a channel of a TFT and a component independent thereof. The component independent of the channel width is derived from an edge (contour portion 30) on which the semiconductor film 15 that determine the channel width and the drain electrode (first source/drain electrode 18) abut on each other. For the aforesaid reasons, the component independent of the channel width is dominated by a current that flows through the two edge points 31. In the present embodiment, the gate electrode 13 is separated from the two edge points 31. At this time, once a place where carriers are derived from impact ionization and the edges of an electrode on which a leakage current is likely to be concentrated are separated from each other by a short distance, an off-state current is drastically decreased.

More particularly, the predetermined distance D0 should be defined in consideration of a misalignment of a pattern accompanying the lithography technology so that a maximum film stress can be approached to a steady-state film stress that is on a level with a stress imposed on the semiconductor film 15 below the center of the first source/drain electrode 18.

By offsetting a gate the two edge points of at least one of two source/drain electrodes are located outside the gate electrode. From this viewpoint, the structure and layout shown in relation to the present embodiment are fundamentally different from those of a simple offset gate.

When the first and second source/drain electrodes 18 and 19 exchange the roles of a source and a drain with each other, the layout shown in FIG. 1 is mirror-symmetrically modified. For example, for the offset gate structure, a layout in which the center of the gate electrode 13 in the width thereof is shifted from the center of the channel toward the first source/drain electrode 18 may be adopted.

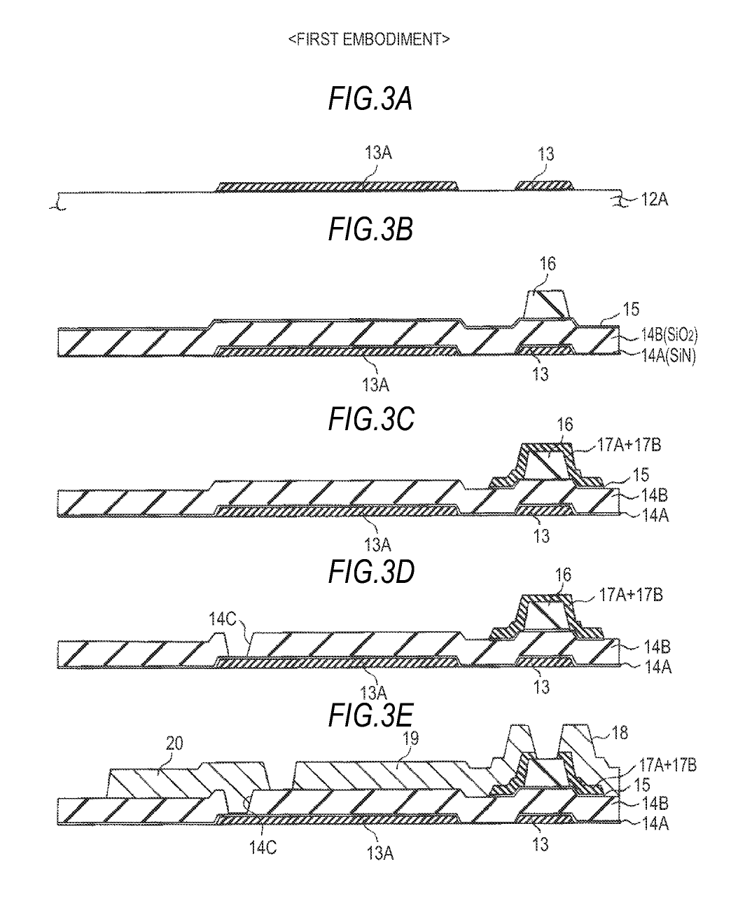

FIGS. 3A to 3E are sectional views showing the process of fabricating a TFT having the foregoing structure. In FIGS. 3A to 3E, a step of forming a semiconductor channel protection film and subsequent steps ending with a step of laying down a wiring will be disclosed. FIGS. 3A to 3E show the TFT and other adjacent elements (for example, a capacitive element and a wiring). The process for laying down the wiring is referred to as an etching stoppage process.

In order to form a bottom gate TFT, first, a gate metal (GM) is coated over the insulating surface of a substrate 9 made of glass or the like, and the patterned gate electrode 13 is formed by processing the gate metal (FIG. 3A).

At this time, a gate metal layer 13A serving as an electrode of a capacitive element or a lining for a wiring is formed in a nearby region.

At a step shown in FIG. 3B, the gate insulating film 14 that is made of a silicon oxide or a silicon nitride and covers the gate electrode 13 is formed, and the semiconductor film 15 serving as a channel formation region of a transistor and being made of an amorphous silicon or a microcrystalline silicon is formed on the gate insulating film 14.

Thereafter, a silicon nitride or the like is coated thick, and patterned in order to form the semiconductor channel protection film 16 in such a manner that the semiconductor channel protection film 16 partially overlaps the upper layer of the gate electrode 13. At this time, when the gate electrode is formed to have the offset structure shown in FIG. 1, the semiconductor channel protection film 16 is unidirectionally deviated from the gate electrode 13.

The source/drain semiconductor film 17A and lower electrode film 17B shown in FIG. 2 are formed according to their forming methods, and then patterned. At this time, etching is performed to remove the semiconductor film 15 from a region other than a region protected by the source/drain semiconductor film 17A and lower electrode film 17B. Eventually, the semiconductor film 15 is left below the semiconductor channel protection film 16 or source/drain semiconductor film 17A as if to be self-aligned with the semiconductor channel protection film 16 or source/drain semiconductor film 17A.

At a step shown in FIG. 3C, a resist (not shown) having a bore at a predetermined position is formed on the upper surface of an upper-layer film (for example, a silicon oxide film 14B) of the bared gate insulating film 14. The silicon dioxide film 14B and silicon nitride film 14A below the silicon dioxide film 14B are etched in order to form a contact hole 14C.

At a step shown in FIG. 3D, the main wiring film 17C and upper electrode film 17D serving as the first and second source/drain electrodes 18 and 19 are formed and sequentially etched in order to create a predetermined pattern. Eventually, the first and second source/drain electrodes 18 and 19 are formed apart from each other above the channel formation region. A wiring 20 coupled to the lower gate metal layer 13A through the contact hole 14C is formed in other region.

At this time, etching may be performed in order to remove the portions of the source/drain semiconductor film 17A and lower electrode film 17B, which are patterned at the step shown in FIG. 3C, lying above the channel formation region, or may be left as shown in FIG. 1. The channel formation region in the semiconductor film 15 can be protected from being damaged during etching owing to the thick semiconductor channel protection film 16.

The second embodiment relates to a bottom gate staggered TFT having a semiconductor channel protection film 16, and is concerned with the (second) case where a convex part of a gate electrode overlaps the linear contour portion 30 at one position.

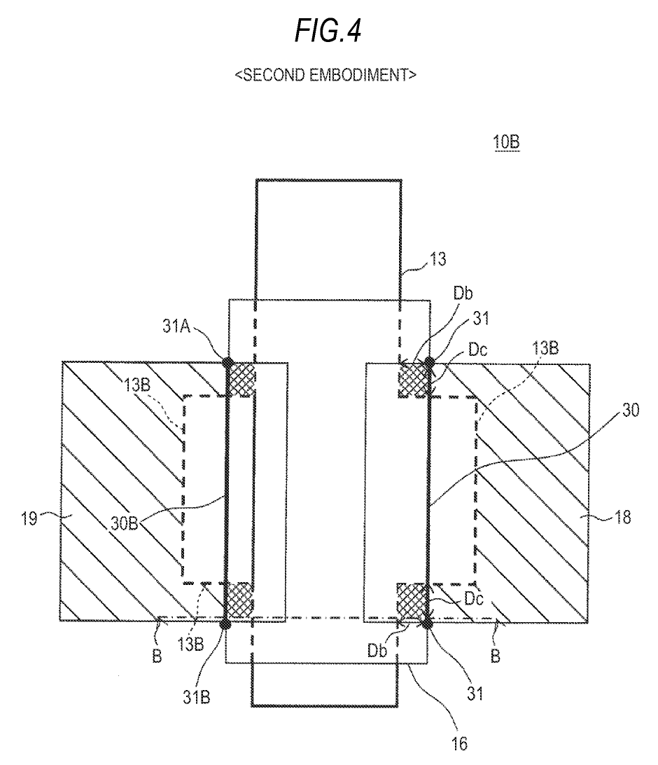

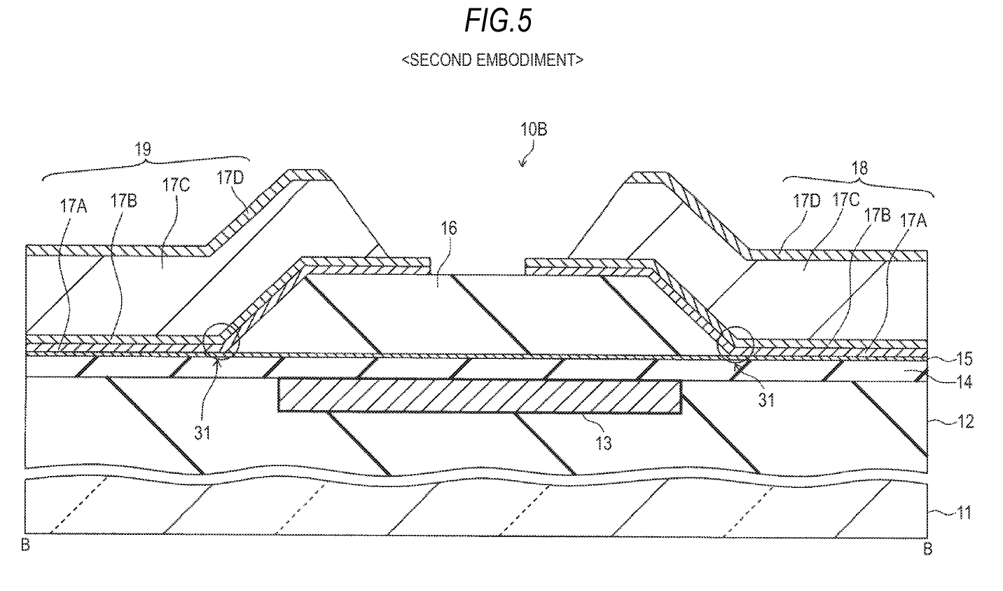

FIG. 4 is a plan view, and FIG. 5 is a sectional view along a B-B cutting-plane line shown in FIG. 4.

As for points at which the present invention is different from the first embodiment (FIG. 1), the first point is that a source and a drain are laterally symmetrical to each other with respect to the center of a channel. The second point is that the gate electrode 13 has convex parts 13B that are seen through planar view to project to a source electrode and a drain electrode respectively. The convex parts 13B overlap the contour portions 30. At this time, the distance Dc from the convex part 13B to the edge point 31 is preferably equal to or longer than the certain distance D0. The edge points 31 are separated from the straight parts of the gate electrode 13 by a distance Db. The distance Db is preferably equal to or longer than the certain distance D0.

In the present embodiment, since a channel formation region dominated by an electric field induced by the gate electrode 13 is separated from the gate electrode 13, an off-state current is largely decreased. From this viewpoint, the present embodiment is as advantageous as the first embodiment is.

In addition, since the convex part 13B overlaps the contour portion 30 over the maximum width, the channel formation region is nearly directly coupled to the first or second source/drain electrode 18 or 19 at nearly any point on the contour portion 30. Therefore, a resistance caused by a source or a drain is drastically smaller than that caused by those included in a simple offset structure.

Compared with the first embodiment, an overlap capacitance (parasitic capacitance) between a gate and a drain or source increases. Also, the effect of a decrease in an on-state resistance is so great that the present embodiment proves useful.

Regions in which a parasitic capacitance is increased are shown as netted areas in FIG. 4. The regions are located outside the contour of the gate electrode 13 and directly electrically coupled to an electric field induced by the gate electrode. Further, the regions are located inside the semiconductor channel protection film 16, and any electrode is not mounted on the regions. Therefore, in the regions, the gate electrode 13 is, in terms of the sectional structure, capacitively coupled to the first or second source/drain electrode 18 or 19 via the thin gate insulating film 14 and semiconductor film 15.

However, as apparent from FIG. 4, the four regions have a small area. When the distance between the gate electrode 13 and edge point 31 is decreased as greatly as possibly to such an extent that a leakage will not increase, that is, when the distance is equal to the predetermined distance D0, the area of the four regions is minimized. The parasitic capacitance is therefore decreased.

In the present embodiment, the distance between the edge point 31 and gate electrode 13 is preferably equal to the predetermined distance D0 in order to decrease both an off-state leakage and a parasitic capacitance.

The TFT in accordance with the present embodiment will prove useful as, for example, a switching element in which the capabilities of a source and a drain are switched depending on the relationship between potentials.

Assuming that the capability of a drain is fixed, an idea that the gate electrode has the convex part only on the side of the first source/drain electrode 18 is also encompassed in the scope of the present embodiment.

In addition, if plural convex parts 13B that intersect the contour portion 30 of one of source and drain electrodes or if the convex part 13B has a wavy shape, the advantage provided by the present embodiment is reduced. Specifically, since a portion of the length between the edge points 31 which the convex part 13B intersects serves as a low-resistance region, if plural rectangular or wavy convex parts 13B are present, the interspaces among the plural convex parts still cause a high resistance. Therefore, an on-state resistance is not decreased satisfactorily. In addition, in the interspaces among the convex parts 13B, similarly to the regions expressed with the netted areas in FIG. 4, an overlap capacitance increases. This leads to an increase in a parasitic capacitance. Therefore, for these two reasons, the layout structure in which the plural convex parts intersect the contour portion 30 is not preferred.

In contrast, in the first embodiment, a layout in which a sole convex part 13B is formed to have a maximum width and separated from the edge points 31 at the ends of the contour portion 30 by a minimum distance (predetermined distance D0) that is necessary to decrease a leakage is most preferable.

In FIG. 4, when a condition Db=Dc=D0 is met, since the area of the regions that are expressed with the netted area and that cause a parasitic capacitance to increase are minimized, it is preferable. Even a condition Db=Dc>D0 is effective in decreasing a parasitic capacitance.

The second requirement for application of the present embodiment is that when the edge points 31 adjoin plural sides of the gate electrode 13, the edge points 31 should be separated from the plural sides by an equal distance.

### 5. Third Embodiment

The present embodiment relates to a bottom gate staggered TFT that includes a semiconductor channel protection film 16, and is concerned with the (third) case where the linear edge of a gate electrode overlaps a concave part of the contour portion 30 at one position on the contour portion.

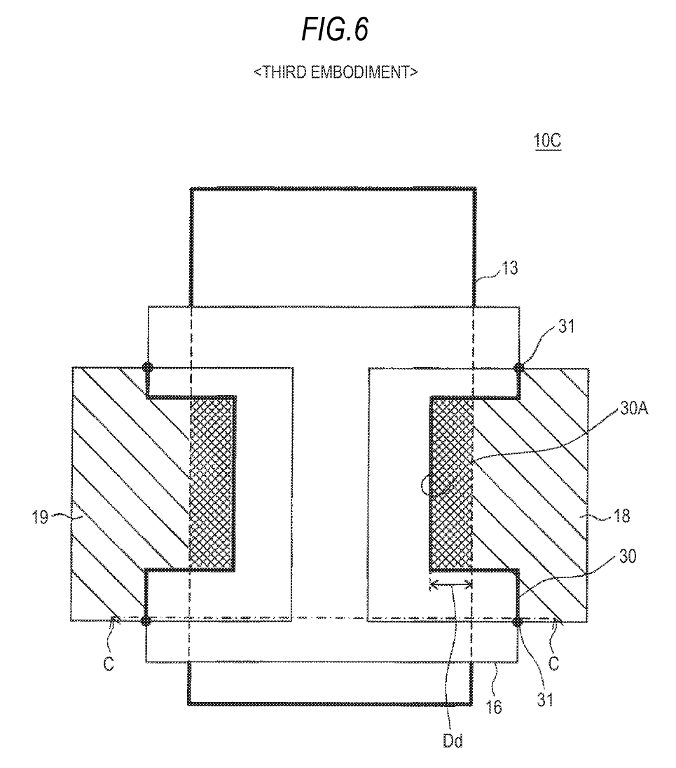

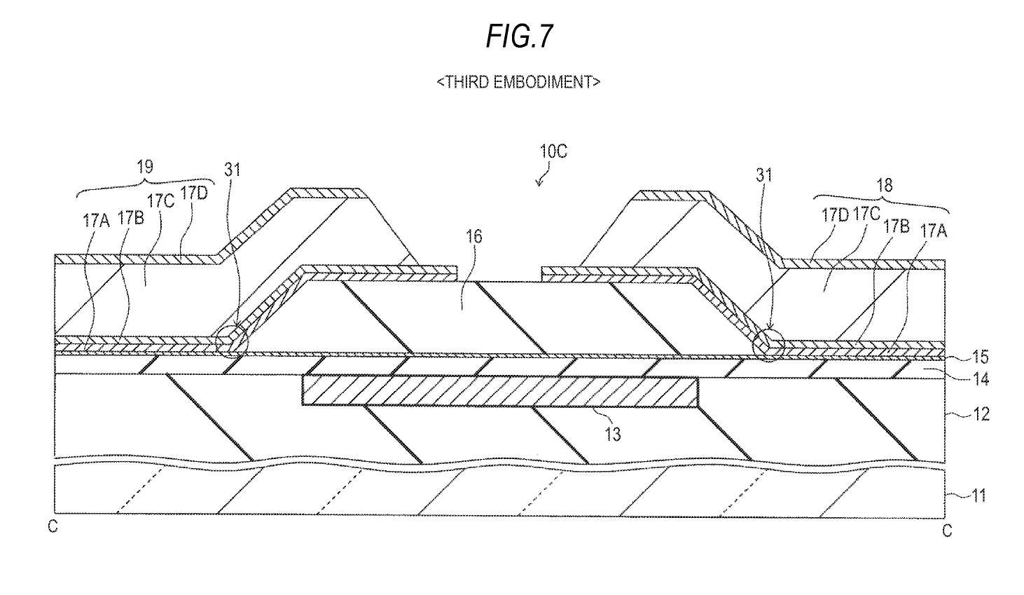

FIG. 6 is a plan view, and FIG. 7 is a sectional view along a C-C cutting-plane line shown in FIG. 6.

The second embodiment (FIG. 4) has such a layout shape that the gate electrode has a convex shape, and the linear contour portion 30 overlaps the convex part.

In contrast, a TFT 10C in accordance with the third embodiment has such a layout shape that the contour portion 30 has a convex part, and the convex part overlaps the linear edge of the gate electrode 13.

More particularly, in FIG. 6, the semiconductor channel protection film 16 has concave parts on the sides of drain and source electrodes respectively. Each of the edges of the semiconductor channel protection film 16 defines the contour portion 30 on which the first or second source/drain electrode 18 or 19 abuts on the semiconductor film 15 at the lower edge of the slope shown in FIG. 7. Therefore, the contour portion 30 is, as shown in FIG. 6, shaped like a broken line that has a convex part 30A projected toward the center of a channel and bends four times. Two points at which the outline of the pattern of the first or second source/drain electrode 18 or 19 meets the broken line (contour portion 30) are points on a border between a contact region (hatched area in the drawing) and a non-contact region, and regarded as the edge points 31.

The layout represents, similarly to the one in the second embodiment, an example of the form in which a gate electrode overlaps a contour portion of a region, in which a source/drain electrode abuts on a semiconductor layer, at one position on the contour portion.

Therefore, the channel formation region in the TFT abuts on the first or second source/drain electrode 18 or 19 over the entire width of the large convex part 30A, and an on-state resistance is decreased. As long as the width of the convex part 13B of the gate electrode 13 included in the second embodiment (the size in the lengthwise direction of the sheet of paper of FIG. 4) is nearly equal to the width of the concave part of the semiconductor protection film 16 (convex part of the contour portion 30) included in the third embodiment, the advantage of the third embodiment substantially corresponds to the advantage of the second embodiment.

In contrast, regions shown as netted areas in FIG. 6 are regions in which the gate electrode 13 is capacitively coupled to the first or second source/drain electrode 18 or 19 via the thin semiconductor film 15. The area of the regions tends to get larger than that of the regions shown in FIG. 4. Therefore, the third embodiment tends to produce a larger parasitic capacitance than the second embodiment does.

However, even when there is difficulty in largely decreasing the distance Db shown in FIG. 4 because of restrictions imposed to decrease a leakage, the distance Dd shown in FIG. 6 can be decreased more greatly because a misalignment alone should be taken into account. Therefore, the parasitic capacitance produced in the third embodiment can be suppressed to be level with that produced in the second embodiment.

The distance Dd may be nullified at a design center. In this case, if the magnitude of a misalignment is large, the convex part 30A may not overlap the edge of the gate electrode 13 though it adjoins the edge thereof. Even in this case, an on-state resistance value increases according to the length of the interspace. However, there is the merit that the parasitic capacitance can be drastically decreased.

When the parasitic capacitance has to be decreased at the sacrifice of an on-state resistance, the foregoing layout design may be adopted.

The three embodiments have been described so far by taking a bottom gate staggered TFT for instance and noting the differences among layout patterns. The present invention can be applied to a top gate staggered type and a planar type using the embodiments as standard layout patterns.

Since the layouts have already been detailed, the other embodiments will be described below in conjunction with schematic plan views and sectional views showing constructions.

### 6. Fourth Embodiment

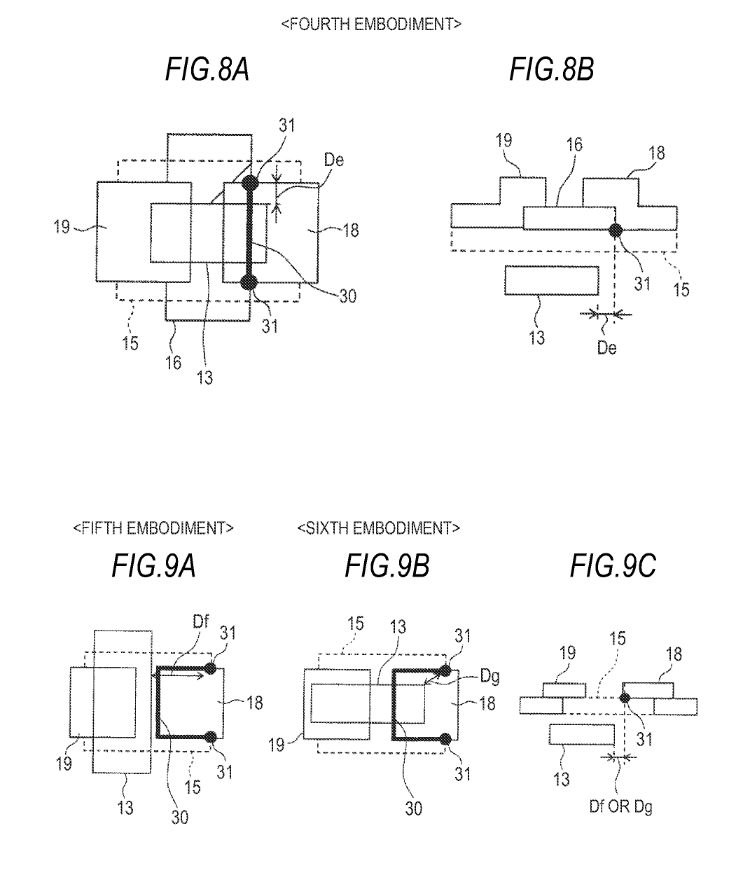

FIG. 8A is a schematic plan view, and FIG. 8B is a schematic diagram showing a construction in a vertical direction. The schematic construction diagram shows an approximate degree to which a semiconductor film having a channel formed therein and a source/drain electrode overlap in the channel length direction. FIG. 8B also shows a gate electrode that adjoins the edge points at the shortest distance.

The fourth embodiment relates to a bottom gate staggered TFT including the semiconductor channel protection film 16, and is concerned with the (fourth) case where the gate electrode 13 overlaps the contour portion 30 over the entire width thereof.

As shown in FIG. 8A, the width of the gate electrode 13 is smaller than the length of the contour portion 30, and the gate electrode 13 overlaps the contour portion 30 over the entire width thereof. The gate electrode 13 is disposed in a layer below the semiconductor film 15, and located close to the edge points 31 at a distance De. The distance De is preferably equal to or longer than the predetermined distance D0. In this case, an off-state leakage is drastically decreased.

The area of the gate electrode 13 is small. If a parasitic capacitance between a source and a gate may be large, the gate electrode 13 may be extended to the source electrode in order to create a pull-out wiring.

The foregoing layout is an example of the form in which a gate electrode overlaps a contour portion of a region, in which a source/drain electrode abuts on a semiconductor film, at a single position on the contour region.

FIG. 9A is a schematic plan view showing the fifth embodiment, and FIG. 9B is a schematic plan view showing the sixth embodiment. FIG. 9C is a schematic diagram showing a construction in a vertical direction that is employed in common by the fifth and sixth embodiments.

The fifth and sixth embodiments are concerned with a case where a bottom gate staggered TFT is devoid of a semiconductor channel protection film. Especially, the fifth embodiment is, similarly to the first embodiment, concerned with the (first) case where the gate electrode 13 does not overlap the contour portion 30. The sixth embodiment is, similarly to the fourth embodiment, concerned with the (fourth) case where the gate electrode 13 overlaps the contour portion 30 over the entire width thereof in the width direction thereof.

As shown in FIG. 9A and FIG. 9B, since the semiconductor channel protection film is absent, the first and second source/drain electrodes 18 and 19 are mounted on the semiconductor film 15 to partially overlap the semiconductor film 15. Therefore, the contour portion 30 corresponds to the contour of the portion of the contour of the source/drain electrode overlapping the semiconductor film, and is shaped like a broken line that bends twice.

The edge points 31 are equivalent to the ends of the contour portion 30, that is, the intersections between the edge of the semiconductor film 15 and the edges of the first or second source/drain electrode 18 or 19.

In the fifth embodiment, the gate electrode 13 adjoins the contour portion 30 but does not overlap the contour portion 30. Nevertheless, since the gate electrode adjoins the contour portion 30, an increase in an on-state resistance is markedly suppressed. Another merit is that a parasitic capacitance on the side of the drain is very small. Above all, since the edge points 31 are located outside the gate electrode 13, an off-state leakage is drastically decreased.

In the sixth embodiment, similarly to the fourth embodiment, the width of the gate electrode 13 is smaller than the length of the contour portion 30, and the gate electrode 13 overlaps the contour portion 30 over the entire width thereof.

In the fifth and sixth embodiments, the distance between the gate electrode 13 and each of the edge points 31 is indicated as the distance Df or distance Dg. The distance Df or Dg is preferably equal to or longer than the predetermined distance D0. Thus, an off-state leakage is largely decreased.

A fabrication process during which the semiconductor channel protection film that is necessary in the first to fourth embodiments is excluded will be described below.

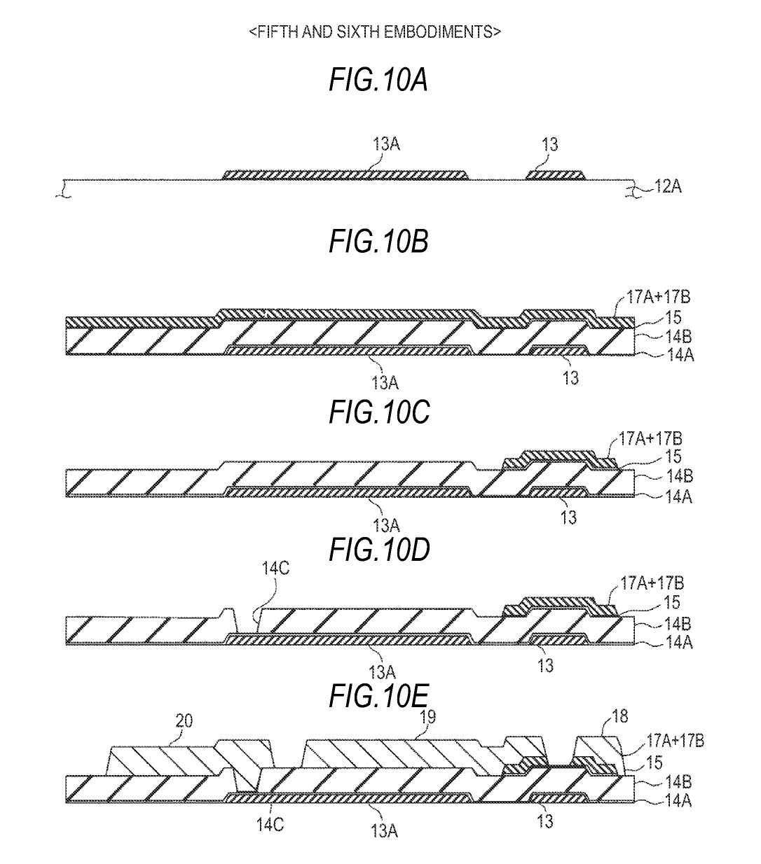

FIGS. 10A to 10E are sectional views showing the process of fabricating a TFT in accordance with the fifth or sixth embodiment. The process for laying down a wiring shown in FIGS. 10A to 10E is referred to as a back channel etching process.

Formation of the gate electrode 13 (and gate metal layer 13A) (FIG. 10A), formation of the silicon nitride film 14A and silicon dioxide film 14B, and formation of the semiconductor film 15 (FIG. 10B) are identical to those included in the etching stoppage process shown in FIGS. 3A to 3E.

In FIG. 10B, the source/drain semiconductor film 17A and lower electrode film 17B are formed without formation of the semiconductor channel protection film.

In FIG. 10C, the formed film is processed to be patterned.

Thereafter, similarly to the process shown in FIGS. 3A to 3E, the contact hole 14C is formed (FIG. 10D), a film providing the first source/drain electrode 18, second source/drain electrode 19, and wiring 20 (main wiring film 17C and upper electrode film 17D) is formed, and the electrodes are separated from each other by performing photolithography and etching.

For the etching, preferably, the source/drain semiconductor film 17A serves as a stopper for stopping etching of the upper layer. However, the source/drain semiconductor film 17A and the semiconductor film 15 that is the bed for the source/drain semiconductor film 17A are made of a semiconductor material. If the etching selectivity is undetermined, the source/drain semiconductor film 17A is carefully etched for fear the semiconductor film 15 may be thinned unnecessarily.

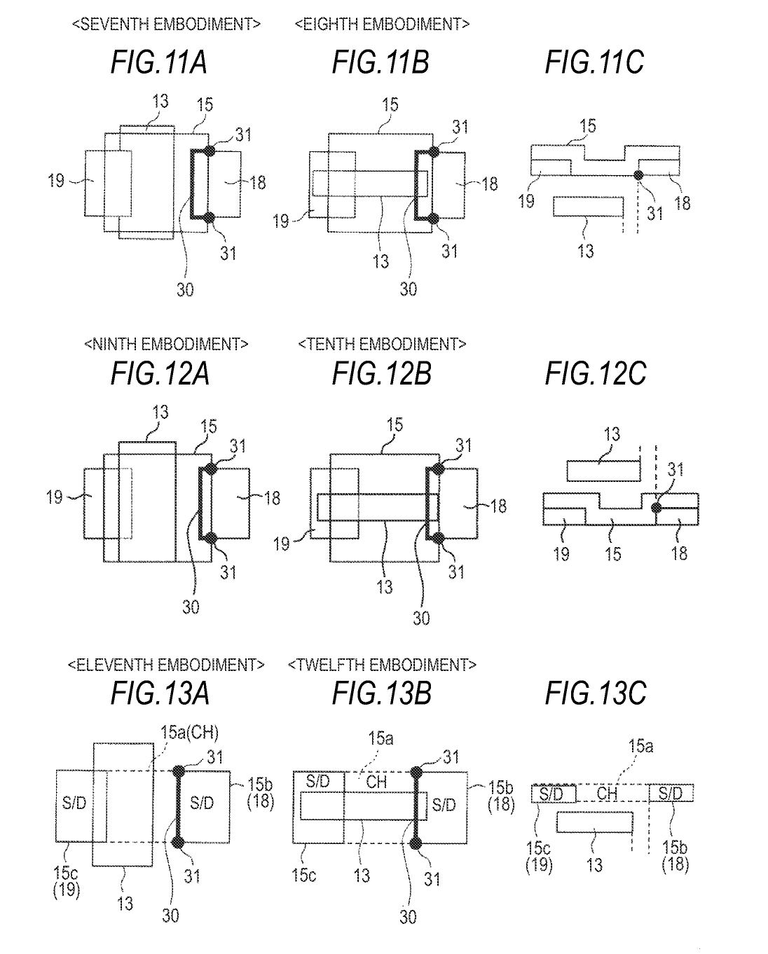

FIG. 11A is a schematic plan view showing the seventh embodiment, and FIG. 11B is a schematic plan view showing the eighth embodiment. FIG. 11C is a schematic diagram showing a construction in a vertical direction that is employed in common by the seventh and eighth embodiments.

The seventh and eighth embodiments are variants of the fifth and sixth embodiments. In relation to the seventh and eighth embodiments, a structure intended to protect the semiconductor film 15 from being damaged during etching shown in FIG. 10E will be disclosed.

In the seventh and eighth embodiments, the first and second source/drain electrodes 18 and 19 are formed (in a lower layer) while being separated from each other. Thereafter, the semiconductor film 15 is formed to cover the first and second source/drain electrodes 18 and 19 including the interspace. Namely, the up-and-down relationship shown in FIGS. 11A and 11B between the first and second source/drain electrodes 18 and 19 and the semiconductor film 15 is reverse to the relationship shown in FIGS. 9A and 9B.

The relationship in a layout pattern between the gate electrode 13 and contour portion 30 employed in the seventh embodiment corresponds to that employed in the fifth embodiment. The relationship in the layout pattern between the gate electrode 13 and contour portion 30 employed in the eighth embodiment corresponds to that employed in the sixth embodiment.

In the seventh and eighth embodiments, since the thin semiconductor film 15 is formed to overlap the first and second source/drain electrodes 18 and 19, the edges of the first and second source/drain electrodes 18 and 19 are preferably forward tapered. However, when the semiconductor film 15 is formed and etched, even if the source/drain electrodes serving as the bed are damaged, since the source/drain electrodes are formed in a thick conducting layer, there is no demerit. At this time, since processing the source/drain electrodes is already completed, the semiconductor film 15 does not incur an adverse effect of processing the source/drain electrodes.

For the foregoing construction, the semiconductor film 15 may be a film made of a polycrystalline silicon. The construction is preferably applied to a case where the semiconductor film 15 is an organic semiconductor film.

FIG. 12A is a schematic plan view showing the ninth embodiment, and FIG. 12B is a schematic plan view showing the tenth embodiment. FIG. 12C is a schematic diagram showing a construction in a vertical direction that is employed in common by the ninth and tenth embodiments.

The ninth and tenth embodiments are variants of the seventh and eighth embodiments. A point of modification lies in that the gate electrode 13 is disposed in a layer above the semiconductor film 15 in order to realize a top gate structure. The other constituent features are identical to those of the seventh and eighth embodiments.

The relationship in a layout pattern between the gate electrode 13 and contour portion 30 employed in the ninth embodiment corresponds to that employed in the seventh embodiment. The relationship in the layout pattern between them employed in the tenth embodiment corresponds to that employed in the eighth embodiment.

FIG. 13A is a schematic plan view showing the eleventh embodiment, and FIG. 13B is a schematic plan view showing the twelfth embodiment. FIG. 13C is a schematic diagram showing a construction in a vertical direction that is employed in common by the eleventh and twelfth embodiments.

The eleventh and twelfth embodiments relate to a bottom gate planar TFT devoid of the semiconductor channel protection film, and are concerned with a case where the contour portion 30 is not an edge of a contact region in which a source/drain electrode abuts on a semiconductor film. More particularly, the semiconductor film 15 contains a channel formation region (CH) 15a and two source/drain regions 15b and 15c (S/D) that contain a reverse-conducting impurity at a high concentration and are formed on the sides of the channel formation region. In this case, the two source/drain regions 15b and 15c function as parts of the first or second source/drain electrode 18 or 19. Therefore, the region on which the source/drain region abuts on the semiconductor film in which a channel is formed refers to a portion of the internal surface of the semiconductor film 15 on which the channel formation region 15a and source/drain region 15b or 15c abut on each other. The contact region is equivalent to the contour portion 30. The ends of the contour portion 30 serve as, as those in the other embodiments, the edge points 31.

The gate electrode 13 is disposed below the semiconductor film 15.

The relationship in a layout pattern between the gate electrode 13 and contour portion 30 employed in the eleventh embodiment corresponds to that employed in the seventh and ninth embodiments. The relationship in the layout pattern between them employed in the twelfth embodiment corresponds to that employed in the eighth and tenth embodiments.

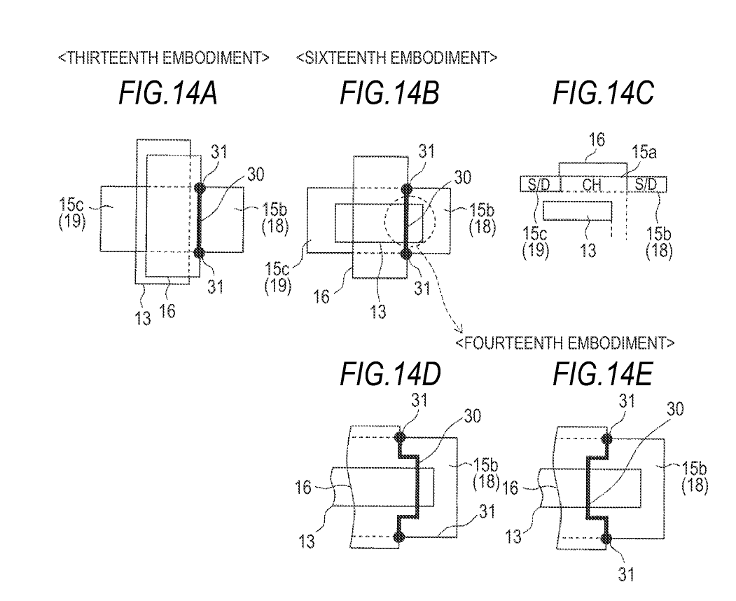

FIG. 14A is a schematic plan view showing the thirteenth embodiment, and FIG. 14B is a schematic plan view showing the sixteenth embodiment. FIG. 14D is a schematic plan view showing part of the fourteenth embodiment. FIG. 14E is a schematic plan view showing part of the fifteenth embodiment. The schematic construction in a vertical direction shown in FIG. 14C is used in common among the thirteenth to sixteenth embodiments.

The thirteenth to sixteenth embodiments are variants of the eleventh and twelfth embodiments relating to a bottom gate planar TFT.

As shown in FIGS. 14A to 14E, the semiconductor channel protection film 16 is disposed to cover the channel formation region 15a. The semiconductor channel protection film 16 can be used as a mask layer to apply a high-concentration impurity to the semiconductor film 15. In the thirteenth to sixteenth embodiments, the mask layer may be left intact as the semiconductor channel protection film 16.

In the embodiments, the planar-view shape of the contour portion 30 can be determined with the shape of the edge of the mask layer. For example, in the fourteenth embodiment (FIG. 14D), a pattern in which the semiconductor channel protection film 16 has a convex part is formed. By reflecting the pattern, the contour portion 30 is formed to have a concave part on the side of a channel. In contrast, in the fifteenth embodiment (FIG. 14E), a pattern in which the semiconductor channel protection film 16 has a concave part is formed. By reflecting the pattern, the contour portion 30 is formed to have a convex part on the side of the channel. The sixteenth embodiment is concerned with a case where the semiconductor channel protection film 16 has a simple rectangular shape.

In the fourteenth to sixteenth embodiments, the gate electrode 13 overlaps the contour portion 30 over the entire width thereof. In the thirteenth embodiment, the gate electrode 13 does not overlap the contour portion 30.

Next, a comparative example will be described in order to clarify the advantages of the present invention.

### Structure of Comparative Example

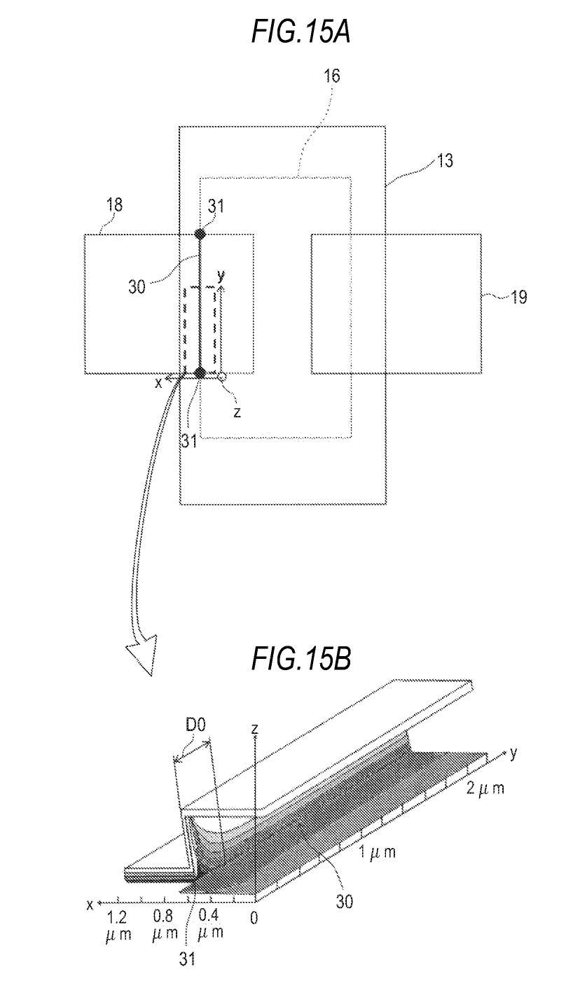

FIG. 15A shows a layout pattern of a comparative example.

In the comparative example, the contour portion 30 defined with an edge of the semiconductor channel protection film 16 that intersects the first source/drain electrode 18 (drain electrode), and the two edge points 31 at the ends of the contour portion are covered with the gate electrode 13.

The same applies to the second source/drain electrode 19 serving as a source electrode.

In the case of the structure of the comparative example, an off-state current increases in a region near a drain electrode in which an electric-field intensity is the highest, that is, on the contour portion 30 defined with a portion of the contour line of the semiconductor channel protection film 16 covered by the first source/drain electrode 18. In particular, a leakage occurring at the edge points 31 becomes a dominative factor of a leakage from the drain electrode of the TFT.

FIG. 15B is a three-dimensional graph indicating the results of simulation to be performed in order to back up the foregoing fact using an electric-field distribution.

As shown in FIG. 15B, a region in which an electric-field intensity is the highest is concentrated on the bottom of an edge of the first source/drain electrode 18. In particular, the electric-field intensity is markedly high at the edge points 31. The electric-field intensity is high on the contour portion 30. The electric-field intensity abruptly rises at a certain position near the edge point 31 along the contour portion 30 extending in a y direction.

The results of simulation demonstrate that separating the channel formation region (region dominated by an electric field induced by the gate electrode 13) from the edge points 31 is effective in decreasing a leakage.

The distance in the y direction from a position, at which the electric-field intensity is much higher than that observed in a steady-state electric-field distribution, to each of the edge points 31 can be estimated as the shortest distance by which the gate electrode 13 should be separated in order to decrease a leakage, that is, the predetermined distance D0.

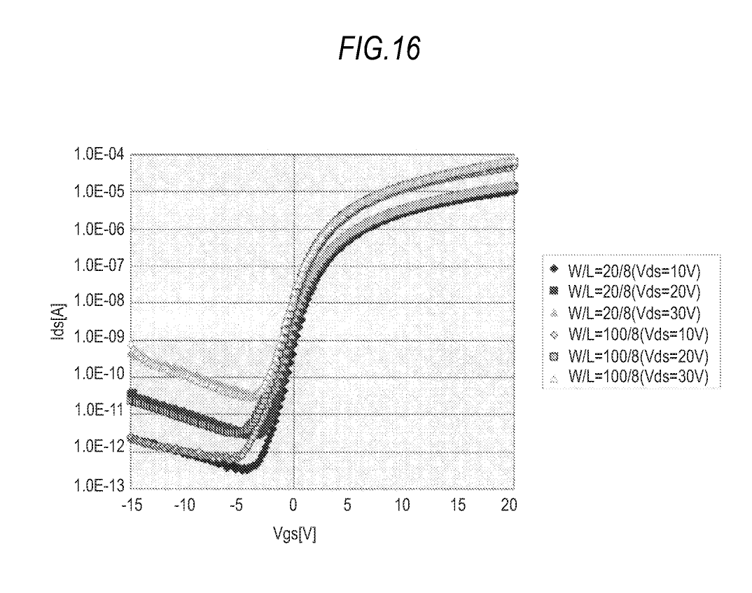

FIG. 16 is a graph indicating measured values of an off-state leakage current associated with values of an operating voltage regarded as a parameter.

As seen from the graph, when the operating voltage (drain voltage Vds) is raised, a rate at which an off-state leakage current increases is larger than a rate at which an operating current (on-state current) increases. This implies that the presence of a weak point, on which an electric field is likely to be concentrated, such as the aforesaid edge points is a major cause of an off-state leakage current.

In the aforesaid first to sixteenth embodiments, the comparative example is improved in terms of a leakage according to the results of simulation performed to create the electric-field distribution. When the gate electrode 13 is formed apart from the edge points 31, an off-state leakage can be drastically suppressed. The distance between the gate electrode and each of the edge points should be designed in consideration of a misalignment of a mask so that the predetermined distance D0 shown in FIG. 15B can be ensured.

According to the first to sixteenth embodiments, merits described below are provided.

First, by adopting a structure in which the gate electrode 13 does not cover a semiconductor-film region for a drain electrode, an electric field can be relaxed. A leakage current occurring when the gate electrode is inactivated (0 V or negative bias) can be decreased without a decrease in an on-state current.

Secondly, a region that does not cover a gate is confined to an edge of a channel (edge points 31). Therefore, a layout making a source and a drain symmetrical to each other can be realized. The layout can be applied to a circuit in which the source and drain are switched for use. This merit is not provided by an asymmetrical layout employed in the first embodiment.

Thirdly, a region that does not cover a gate is confined to an edge of a channel. Therefore, while a variance in a current capability deriving from a variance in processing of a drain electrode and occurring when a transistor is turned on is suppressed, a leakage current can be decreased.

Fourthly, in a structure in which the gate electrode 13 does not cover an edge of a channel, when the channel edge is notched, a fringe capacitance on the channel edge can be decreased. Since a parasitic capacitance of a circuit can be decreased, a high-speed operation can be achieved.

Next, an embodiment in which a TFT having the aforesaid structure is adopted as an element of a pixel circuit included in a display device will be described below by taking an organic electroluminescent (EL) display for instance.

The organic EL display has attracted attention as a flat display type display device. Since the display device utilizes the luminous phenomenon of organic light-emitting elements, the display device has such excellent features as a wide viewing angle and low power consumption. In addition, the display device has the merit of a high response speed.

As the driving method for the display device, an active matrix method permitting quicker response than a passive matrix method does is preferred.

An organic EL display that adopts the active matrix driving method needs at least a light emitting element made of an organic material, a driving element that drives the light-emitting element, and a switching element that controls the brightness or darkness of a pixel. Any of the first to sixteenth thin-film transistors is adopted as the driving element or switching element. At this time, the TFT having a symmetrical layout in accordance with the first or second embodiment has to be adopted as the switching element. As the driving element, either the TFT having the symmetrical layout or the TFT having an asymmetrical layout may be adopted.

A more detailed construction of a display device and an example of a circuit will be described below.

### [Display Device and Example of Construction of Pixel Circuit]

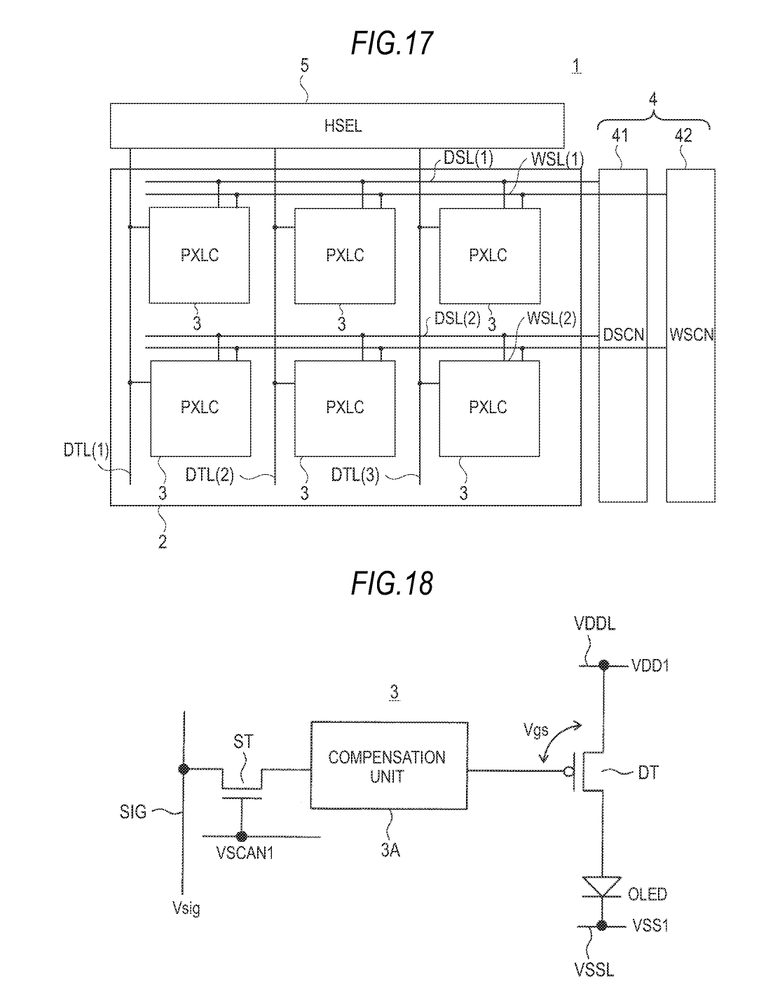

FIG. 17 shows a major construction of an organic EL display in accordance with the present embodiment of the present invention.

An organic EL display 1 shown in FIG. 17 includes a pixel array 2 having plural pixel circuits (PXLC) 3 arranged in the form of a matrix, and vertical drive circuits (V scanners) 4 and horizontal drive circuits (H selectors; HSEL) 5 that drive the pixel array 2.

The number of V scanners 4 depends on the arrangement of the pixel circuits 3. Herein, the V scanner 4 includes a horizontal pixel line drive circuit (DSCN) 41 and a writing signal scan circuit (WSCN) 42. Aside from the V scanner 4 and H selector 5, a circuit that gives a clock signal to the V scanner and H selector, a control circuit (CPU), and other circuits that are not shown are included.

The circuit diagram of FIG. 18 shows an organic light-emitting diode and a pixel circuit disposed in each pixel in order to control the light-emitting diode.

The pixel circuit 3 shown in FIG. 18 includes an organic light-emitting diode OLED serving as an electro-optic element, a sampling transistor ST realized with an NMOS transistor, a driving transistor DT realized with a PMOS transistor, and a compensation unit 3A.

The cathode of the organic light-emitting diode OLED is connected to a second supply voltage line VSS1.

The driving transistor DT is connected between the anode of the organic light-emitting diode OLED and a first supply voltage line VDD1. The driving transistor DT controls an amount of driving current that flows based on a potential difference between the first supply voltage line VDD1 and second supply voltage line VSS1.

A property of the driving transistor DT, especially, a threshold voltage Vt thereof directly affects an amount of driving current to be fed to the organic light-emitting diode OLED. If the threshold voltage Vt varies, the luminance of light emanating from the organic light-emitting diode OLED varies. In addition, in order to improve the uniformity in the luminance of emitted light, a variance in a property of a device called a so-called mobility μ has to be suppressed. The compensation unit 3A is included in order to compensate the variances. The compensation unit 3A may have an arbitrary construction.

The compensation unit 3A is connected between one of the source and drain of the sampling transistor ST and the gate of the driving transistor DT. However, the connection is merely shown as a typical example. Strictly, an element (capacitor or a transistor) connected between the anode of the organic light-emitting diode OLED and the gate of the driving transistor DT is included in the compensation unit 3A.

The other one of the source and drain of the sampling transistor ST is connected onto a signal input line SIG. A data voltage Vsig is applied to the signal input line SIG. The sampling transistor ST samples data, which should be displayed by the pixel circuit, at appropriate timing during a data voltage application period.

The sampling transistor ST may also be used as a transistor that fetches, for example, an offset level (initial level) and is included in the compensation unit 3A. In this case, the offset level and data voltage Vsig have to be applied alternately onto the signal input line SIG.

Therefore, the capabilities of the source and drain of the sampling transistor ST are frequently switched according to the potentials at the node on the side of the compensation unit 3A and the node on the side of the signal input line SIG.

As the sampling transistor ST, the TFT having a symmetrical layout out of the TFTs in accordance with the first to sixteenth embodiment should be adopted.

According to the active matrix driving method, data writing to be performed by the sampling transistor ST and light emission are sequentially begun at each of pixels included in the array of pixels. Terminating light emission is arbitrarily controlled to be performed during a driving period for any other pixel. Therefore, as long as active matrix driving is performed, a high luminance is attained with a low current.

The driving transistor DT for use in controlling light emission has the source thereof connected to the anode of the organic light-emitting diode OLED and has the drain thereof connected to a positive power supply. Therefore, the capabilities of the source and drain are normally not switched. As the driving transistor DT, not only a TFT having a symmetrical layout but also a TFT having an asymmetrical layout among the TFTs in accordance with the first to sixteenth embodiments can be adopted.

The sampling transistor ST may be realized with a PMOS transistor, and the driving transistor DT may be realized with an NMOS transistor.

In the present embodiment, any of the TFTs described as the first to sixteenth embodiments may be adopted as the driving transistor DT or sampling transistor ST shown in FIG. 16. A merit described below is provided.

In the TFT having any of the aforesaid constructions, edge points and a gate electrode are separated from each other. Therefore, the TFT has such features as a small off-state leakage current, a low on-state resistance, and a low parasitic capacitance in a well-balanced manner. Therefore, in a thin-film transistor employed in a display device, a defect such as a flickering point or a glowing point derived from an increase in a leakage current flowing between a source electrode and a drain electrode during a period during which a gate is inactivated can be effectively prevented. Since the thin-film transistor can operate responsively to a high frequency, the thin-film transistor can be applied to a display exhibiting high motion-picture display performance. Further, since an on-state resistance is low, display with a high luminance can be achieved.

In addition, an off-state leakage current is suppressed and an on-state resistance is low. Therefore, a current loss is limited. Eventually, the power consumption of a display device is decreased.

Any of the TFTs in accordance with the aforesaid embodiments can be adopted as an element of a pixel circuit included in an LED display device that uses an LED other than an organic EL element (a type of LED) as a light-emitting element or a plasma display device. The TFTs in accordance with the aforesaid first to sixteenth embodiments can be preferably applied not only to the display device but also so any usage in which a small leakage, a low on-state resistance, and a low parasitic capacitance have to be simultaneously satisfied.

It should be understood by those skilled in the art that various modifications, combinations, sub-combinations and alterations may occur depending on design requirements and other factors insofar as they are within the scope of the appended claims or the equivalents thereof.

What is claimed is:

1. A thin film transistor comprising:
an insulating film;
a gate electrode in the insulating film, the gate electrode having a periphery in plan view;
a semiconductor thin film on the insulating film;
a channel protection layer on the semiconductor substrate, the channel protection film also having a periphery with two oppositely facing edges in the plan view;
a first electrode on the semiconductor thin film with a portion overlying one edge of the channel protection layer;
a second electrode on the semiconductor thin film with a portion overlying the other edge of the channel protection layer;
wherein,
in the plan view, edge points exist where the first or second electrodes overlie the edges of the channel protection layer, an edge point being a portion along the periphery of the channel protection layer, and
in the plan view, at least one edge point lies outside of the periphery of the gate electrode.

2. The thin film transistor of claim 1, wherein in the plan view, at least one edge point of each of the first and second electrodes lies outside of the periphery of the gate electrode.

3. The thin film transistor of claim 1, wherein in the plan view, at least one of the edges of the channel protection layer has a cutout portion.

4. The thin film transistor of claim 3, wherein in the plan view, the respective first or second gate electrode extends into the at least one cut out portion.

5. The thin film transistor of claim 3, wherein in the plan view, each edge of the channel protection layer has a cut out portion and the first and second gate electrodes extend into their respective cut out portions.

6. The thin film transistor of claim 1, wherein in the plan view, the gate electrode is wider than the channel protection layer.

7. The thin film transistor of claim 1, wherein the first and second electrodes are made of a low resistance wiring material.

8. The thin film transistor of claim 1, wherein at least one of the first and second electrodes is made of titanium.

9. The thin film transistor of claim 1, wherein, in plan view, center of the gate electrode is offset from a center of the channel protection film.

10. The thin film transistor of claim 1, wherein the surface of the gate electrode is flush with the surface of the insulating film.

11. A method of producing a thin film transistor comprising the steps of:
forming an insulating film;
forming a gate electrode in the insulating film with a periphery in plan view;
forming a semiconductor thin film on the insulating film;
forming a channel protection layer on the semiconductor substrate, which also has a periphery with two oppositely facing edges in the plan view;
forming a first electrode on the semiconductor thin film with a portion overlying one edge of the channel protection layer;
forming a second electrode on the semiconductor thin film with a portion overlying the other edge of the channel protection layer;
wherein,
in the plan view, edge points exist where the first or second electrodes overlie the edges of the channel protection layer, an edge point being a portion along the periphery of the channel protection layer, and
in the plan view, at least one edge point lies outside of the periphery of the gate electrode.

12. The method of claim 11, wherein in the plan view, at least one edge point of each of the first and second electrodes lies outside of the periphery of the gate electrode.

13. The method of claim 11, wherein in the plan view, at least one of the edges of the channel protection layer has a cutout portion.

14. The method of claim 13, wherein in the plan view, the respective first or second gate electrode extends into the at least one cut out portion.

15. The method of claim 13, wherein in the plan view, each edge of the channel protection layer has a cut out portion and the first and second gate electrodes extend into their respective concave cut out portions.

16. The thin film transistor of claim 1, wherein in the plan view, the gate electrode is wider than the channel protection layer.

17. The thin film transistor of claim 1, wherein the first and second electrodes are made of a low resistance wiring material.

18. The thin film transistor of claim 1, wherein at least one of the first and second electrodes is made of titanium.

19. The thin film transistor of claim 1, wherein, in plan view, center of the gate electrode is offset from a center of the channel protection film.

20. The thin film transistor of claim 1, wherein the surface of the gate electrode is flush with the surface of the insulating film.

21. A thin film transistor comprising:
a semiconductor thin film;
a gate electrode, the gate electrode having a periphery in plan view;
a first electrode connected to the semiconductor thin film, the first electrode having a portion extending in plan view toward the gate electrode in a first direction, the portion having an edge facing the gate electrode; and
a second electrode connected to the semiconductor thin film, the second electrode having a portion extending in plan view toward the gate electrode in a second direction opposite the first direction, the portion having an edge facing the gate electrode;
wherein,
at least a portion of one of the edges of the first and second electrodes lies outside of the periphery of the gate electrode in the plan view.

22. The thin film transistor of claim 21, wherein a portion of each of the edges of the first and second electrodes lies outside of the periphery of the gate electrode in the plan view.
